(19) United States
(12) Patent Application Publication
(10) Pub. No.: US 2025/0176376 A1
(43) Pub. Date: May 29, 2025

(54) Display Device

(71) Applicant: LG Display Co., Ltd., Seoul (KR)

(72) Inventors: Keong Jin Lee, Paju-si (KR); Hong Man MOON, Paju-si (KR); Joo Bong HYUN, Paju-si (KR); So Yeon KIM, Paju-si (KR)

(21) Appl. No.: 18/942,279

(22) Filed: Nov. 8, 2024

(30) Foreign Application Priority Data
Nov. 27, 2023 (KR) 10-2023-0166918

(51) Int. Cl. H10K 59/126; H10K 59/80

(52) U.S. Cl. CPC H10K 59/126; H10K 59/879

(57) ABSTRACT

A display device including a plurality of light-emitting devices is provided. The plurality of the light-emitting devices may be disposed on a substrate. A first insulating layer may be disposed on the plurality of light-emitting devices. Lenses may be disposed on the first insulating layer. The lenses may be disposed to respectively correspond to the plurality of light-emitting devices. A first light-shielding pattern may be disposed between the substrate and the first insulating layer. The first light-shielding pattern may be disposed to correspond to an area between the plurality of light-emitting devices. A second light-shielding pattern may be disposed on the first insulating layer. The second shielding pattern may overlap the first light-shielding pattern. The second light-shielding pattern may include a central portion and an edge portion disposed around the central portion. The edge portion may be inclined with respect to the central portion.

### CROSS-REFERENCE TO RELATED APPLICATION

This application claims the benefit of Republic of Korea Patent Application No. 10-2023-0166918, filed on Nov. 27, 2023, which is hereby incorporated by reference in its entirety.

### BACKGROUND

### Field

The present disclosure relates to a display device capable of preventing or at least reducing light leakage.

### Discussion of the Related Art

Recently, with the advent of a full-scale information age, display devices capable of visually expressing electrical information signals have rapidly developed. Correspondingly, various display devices, such as liquid crystal display devices (LCDs) and organic light-emitting display devices (OLEDs), have been developed and used in various fields.

Among display devices, a light-emitting display device includes a self-light-emitting device as a light-emitting device, and thus does not need a separate light source, which is used for a non-light-emitting display device. Therefore, a light-emitting display device has advantages of a light weight and a thin profile. Further, a light-emitting display device has no limitation on viewing angle due to the self-light-emitting properties thereof.

Such a light-emitting display device may include lenses respectively corresponding to a plurality of light-emitting devices in order to control the viewing angle for reasons of privacy protection, information protection, application thereof to vehicular display devices, etc.

Light emitted from the light-emitting devices may not only travel to the lenses corresponding thereto, but also may spread in all directions. At this time, light that is emitted from the light-emitting devices and travels to areas between the lenses is reflected by light-shielding components, such as light-shielding patterns provided between the lenses, and is re-reflected by reflective components included in the light-emitting devices. In this way, light emitted from the light-emitting devices reaches lenses that do not correspond thereto, which may cause light leakage. This may also cause deterioration in cut-off effect in a display device requiring control of the viewing angle.

### SUMMARY

Accordingly, the present disclosure is directed to a display device that substantially obviates one or more problems due to limitations and disadvantages of the related art.

An object of the present disclosure is to provide a display device capable of preventing or at least reducing light leakage by preventing or at least reducing light emitted from a light-emitting device from being reflected to the light-emitting device by light-shielding components provided in a non-open area or by adjusting an angle at which the light is reflected to the light-emitting device so that the light re-reflected from the light-emitting device does not reach another lens that does not correspond to the light-emitting device.

Additional advantages, objects, and features of the disclosure will be set forth in part in the description which follows and in part will become apparent to those having ordinary skill in the art upon examination of the following or may be learned from practice of the disclosure. The objects and other advantages of the disclosure may be realized and attained by the structure particularly pointed out in the written description and claims hereof as well as the appended drawings.

In a display device of the present disclosure, a first light-shielding pattern and a second light-shielding pattern are provided in a non-open area and any one thereof is formed to have an inclined edge portion. Thus, it is possible to prevent or at least reduce light that is emitted from a light-emitting device and travels to the non-open area from being reflected to the light-emitting device or to prevent or at least reduce the light re-reflected from the light-emitting device from reaching another lens that does not correspond to the light-emitting device, thereby preventing or at least reducing light leakage.

To achieve these objects and other advantages and in accordance with the purpose of the disclosure, as embodied and broadly described herein, a display device includes a plurality of light-emitting devices disposed on a substrate, a first insulating layer disposed on the plurality of light-emitting devices, lenses disposed on the first insulating layer so as to respectively correspond to the plurality of light-emitting devices, a first light-shielding pattern disposed between the substrate and the first insulating layer so as to correspond to an area between the plurality of light-emitting devices, and a second light-shielding pattern disposed on the first insulating layer while overlapping the first light-shielding pattern, wherein the second light-shielding pattern includes a central portion and an edge portion formed around the central portion so as to be inclined with respect to the central portion.

Further, a display device comprises a plurality of light-emitting devices disposed on a substrate; a first insulating layer disposed on the plurality of light-emitting devices; a plurality of lenses disposed on the first insulating layer, the plurality of lenses disposed to respectively correspond to the plurality of light-emitting devices; a first light-shielding pattern disposed between the substrate and the first insulating layer, the first light-shielding pattern disposed to correspond to an area between the plurality of light-emitting devices; and a second light-shielding pattern disposed on the first insulating layer, the second light-shielding pattern overlapping with the first light-shielding pattern. The first light-shielding pattern may include a central portion and an edge portion disposed around the central portion, and the edge portion may be inclined with respect to the central portion.

Further, a display device comprises: a plurality of light-emitting devices disposed on a substrate; a first insulating layer disposed on the plurality of light-emitting devices; a plurality of lenses disposed on the first insulating layer, the plurality of lenses disposed to respectively correspond to the plurality of light-emitting devices; a first light-shielding pattern disposed between the substrate and the first insulating layer, the first light-shielding pattern disposed to correspond to areas between the plurality of light-emitting devices; a second light-shielding pattern disposed on the first insulating layer, the second light-shielding pattern overlapping with the first light-shielding pattern; and a third light-shielding pattern disposed on the first insulating layer and covering the second light-shielding pattern. The third light-shielding pattern may include a central portion and an edge portion disposed around the central portion, and the edge portion may be inclined with respect to the central portion.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1A is a plan view of a display device of the present disclosure in accordance with one embodiment;

FIGS. 1B and 1C are enlarged plan views of a portion in FIG. 1A in accordance with one embodiment;

FIG. 2 is a plan view of display devices according to first and second embodiments of the present disclosure;

FIG. 3 is a cross-sectional view taken along line I-I′ in FIG. 2 in accordance with one embodiment;

FIG. 4A is a cross-sectional view taken along line II-II' in FIG. 2 in accordance with the first embodiment;

FIG. 4B is a view showing a path of light emitted from a light-emitting device in FIG. 4A in accordance with one embodiment;

FIGS. 5A, 5B, 5C are views showing various modified examples of portion A1 in FIG. 4A in accordance with one embodiment;

FIG. 6 is a cross-sectional view taken along line II-II′ in FIG. 2 in accordance with the second embodiment;

FIGS. 7A, 7B, and 7C are views showing various modified examples of portion A2 in FIG. 6 in accordance with one embodiment;

FIG. 8 is a plan view of display devices according to third and fourth embodiments of the present disclosure;

FIG. 9 is a cross-sectional view taken along line III-III′ in FIG. 8 in accordance with the third embodiment;

FIG. 10 is a cross-sectional view taken along line III-III′ in FIG. 8 in accordance with the fourth embodiment;

FIGS. 11A and 11B are views showing modified examples of portion A3 in FIG. 9 and portion A4 in FIG. 10 in accordance with one embodiment;

FIG. 12 is a cross-sectional view of a display device according to a fifth embodiment of the present disclosure; and

FIGS. 13A to 13D are graphs showing the intensity of light according to viewing angle in the display devices according to the first to fourth embodiments of the present disclosure.

### DETAILED DESCRIPTION

Advantages and features of the present disclosure and methods for achieving the same will be made clear from embodiments described below in detail with reference to the accompanying drawings. The present disclosure may, however, be embodied in many different forms, and should not be construed as being limited to the embodiments set forth herein. Rather, these embodiments are provided so that this disclosure will be thorough and complete, and will fully convey the scope of the disclosure to those skilled in the art. The present disclosure is defined only by the scope of the claims.

In the drawings for explaining the exemplary embodiments of the present disclosure, for example, the illustrated shape, size, ratio, angle, and number are given by way of example, and thus, are not limited to the disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear.

The terms “comprises”, “includes”, and/or “has”, used in this specification, do not preclude the presence or addition of other elements unless used along with the term “only”. The singular forms are intended to include the plural forms as well, unless the context clearly indicates otherwise.

In the interpretation of constituent elements, the constituent elements are interpreted as including an error range even if there is no explicit description thereof.

In the description of the various embodiments, when describing positional relationships, for example, when the positional relationship between two parts is described using “on”, “above”, “below”, “next to”, or the like, one or more other parts may be located between the two parts unless the term “directly” or “closely” is used.

In the description of the various embodiments of the present disclosure, when describing temporal relationships, for example, when the temporal relationship between two actions is described using “after”, “subsequently”, “next”, “before”, or the like, the actions may not occur in succession unless the term “directly” or “just” is used therewith.

It may be understood that, although the terms “first”, “second”, etc. may be used herein to describe various elements, these elements are not to be limited by these terms. These terms are merely used to distinguish one element from another. Therefore, in the present specification, an element indicated by “first” may be the same as an element indicated by “second” without exceeding the technical scope of the present disclosure, unless otherwise mentioned.

A first horizontal axis direction, a second horizontal axis direction, and a vertical axis direction should not be construed as only a geometric relationship where a relationship therebetween is strictly perpendicular, and may denote having a broader directionality within a scope where elements of the present disclosure operate functionally.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

The respective features of the various embodiments of the present disclosure may be partially or entirely coupled to and combined with each other, and various technical linkages and modes of operation thereof are possible. These various embodiments may be performed independently of each other or may be performed in association with each other.

Wherever possible, the same reference numerals will be used throughout the drawings to refer to the same or like parts. Because a scale of each of the elements illustrated in the accompanying drawings is different from an actual scale for convenience of description, the disclosure is not limited to the scale illustrated in the drawings.

Hereinafter, a preferred example of a display device according to an embodiment of the present disclosure will be described in detail with reference to the accompanying drawings.

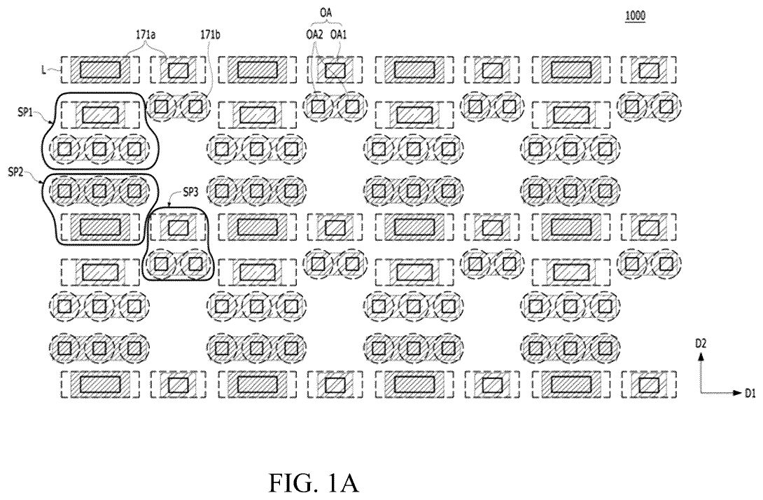

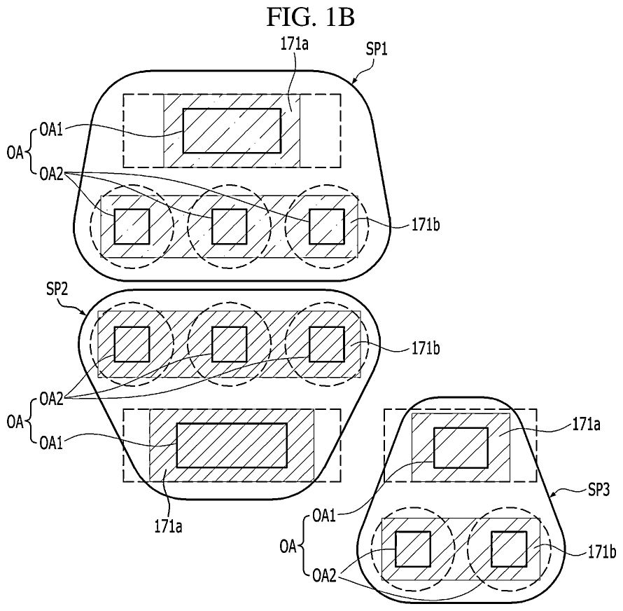

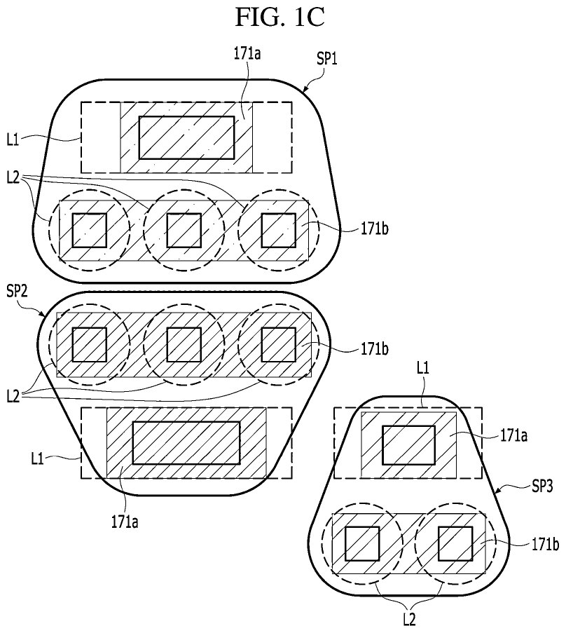

FIGS. 1A to 1C are plan views of a display device of the present disclosure.

Referring to FIGS. 1A to 1C, the display device 1000 of the present disclosure may include a plurality of unit pixels. Each of the plurality of unit pixels may include a first sub-pixel SP1, a second sub-pixel SP2, and a third sub-pixel SP3. The first to third sub-pixels SP1, SP2, and SP3 may be sub-pixels that emit light of different colors. For example, each of the first to third sub-pixels SP1 to SP3 may be a sub-pixel that emits one of red light, green light, and blue light.

The first to third sub-pixels SP1, SP2, and SP3 may have different area ratios. A first lower electrode 171a and a second lower electrode 171b of each of the first to third sub-pixels SP1, SP2, and SP3 and a light-emitting portion and open areas OA (OA1 and OA2) of each of the first to third sub-pixels SP1, SP2, and SP3 may have different area ratios from those of the other sub-pixels. The area of each of the first to third sub-pixels SP1, SP2, and SP3 may be determined in consideration of the lifespan and luminous efficiency of the light-emitting device that emits light of a color corresponding thereto. That is, a sub-pixel that emits short-wavelength light may have a larger area than the other sub-pixels, and a sub-pixel that emits long-wavelength light may have a smaller area than the other sub-pixels. In the present disclosure, the area ratios of the sub-pixels that emit light of different colors are set to be different from each other, thereby making the lifespans and luminous efficiencies of the light-emitting devices of the sub-pixels uniform. For example, as shown in FIG. 1A to 1C, the second sub-pixel SP2 may have a larger area than the first and third sub-pixels SP1 and SP3, and the third sub-pixel SP3 may have a smaller area than the first and second sub-pixels SP1 and SP2. However, the disclosure is not limited thereto. The arrangement and area ratios of the first to third sub-pixels SP1, SP2, and SP3 may be set to be different from those described above.

The first sub-pixel SP1 and the second sub-pixel SP2 may be alternately disposed in a second direction D2. The third sub-pixel SP3 may be disposed adjacent to the first sub-pixel SP1 and the second sub-pixel SP2 in a first direction D1 that intersects the second direction D2. Here, the first direction D1 and the second direction D2 may be directions that perpendicularly intersect each other. However, the placement of the first to third sub-pixels SP1, SP2, and SP3 of the present disclosure is not limited thereto.

Referring to FIGS. 1B and 1C, each of the first to third sub-pixels SP1, SP2, and SP3 may include a first lower electrode 171a and a second lower electrode 171b. The first lower electrode 171a and the second lower electrode 171b may be provided independently of each other and may be driven independently by different driving circuits. The second lower electrode 171b may include a plurality of second open areas OA2. The second lower electrode may be provided in plural so as to correspond to the plurality of open areas respectively.

The first lower electrode 171a and the second lower electrode 171b may be formed to have different areas. In addition, the first lower electrodes 171a of the first to third sub-pixels SP1, SP2, and SP3 may be formed to have different area ratios. The second lower electrodes 171b of the first to third sub-pixels SP1, SP2, and SP3 may also be formed to have different area ratios.

The first lower electrode 171a may be longer in the first direction D1 than in the second direction D2. The first lower electrode 171a may include one first open area OA1. The second lower electrode 17b may also be longer in the first direction D1 than in the second direction D2. In addition, the second lower electrode 171b may include a plurality of second open areas OA2. An area except for the first and second open areas OA1 and OA2 may be defined as a non-open area.

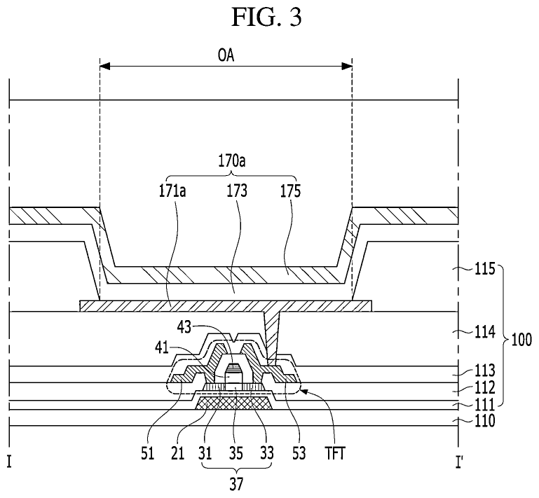

The open areas OA1 and OA2 may be areas in which light is emitted. For example, each of the open areas OA1 and OA2 may be an area exposed from a bank (115 in FIG. 3). The bank may be disposed between the light-emitting devices (170a in FIG. 3). For example, each of the light-emitting devices 170a in which an intermediate layer 173 is disposed between a first lower electrode 171a and an upper electrode 175, may emit light in one of the open areas OA. The open areas OA may include a first open area OA1 corresponding to the first lower electrode 171a and a second open area OA2 corresponding to the second lower electrode 171b. The second open area OA2 may have a different area from the first open area OA1.

The first open area OA1 corresponding to the first lower electrode 171a may be provided in the first direction D1 of the first lower electrode 171a. The first open area OA1 may be longer in the first direction D1 than in the second direction D2.

The plurality of second open areas OA2 corresponding to the second lower electrode 171b may be disposed in a row within the second lower electrode 171b so as to be spaced apart from each other in the first direction D1. Each of the plurality of second open areas OA2 may be formed such that the length thereof in the first direction D1 is similar to the length thereof in the second direction D2.

There may be provided a first lens L1 corresponding to the first open area OA1 of the first lower electrode 171a and a plurality of second lenses L2 corresponding to the plurality of second open areas OA2 of the second lower electrode 171b. The first lens L1 and the plurality of second lenses L2 may have different shapes. The first lens L1 and each of the second lenses L2 may have different area ratios in plan view.

In correspondence with the shape of the first open area OA1 of the first lower electrode 171a, the first lens L1 may be longer in the first direction D1 than in the second direction D2. The first lens L1 may be sized to cover at least the entirety of the first open area OA1 of the first lower electrode 171a. In addition, the first lens L1 may be provided above the first lower electrode 171a while having a larger area than the first open area OA1 and extending over at least the length of the first lower electrode 171a in the first direction D1. The first lens L1 may be implemented as a semicylindrical lens having a length in the first direction D1. For example, the first lens L1 may be implemented as a hemi-ellipsoidal lens that is cut along the long axis thereof.

The semicylindrical first lens L1 may have a rectangular section in plan view and may have a semicircular section when cut along a cutting line extending in the second direction D2. In addition, the hemi-ellipsoidal first lens L1 may have an elliptical section when viewed in plan. Accordingly, the first lens L1 may limit the viewing angle in the second direction D2 without limiting the viewing angle in the first direction D1.

Each of the second lenses L2 may be sized to completely cover a corresponding one of the plurality of second open areas OA2 of the second lower electrode 171b. In addition, the length of each of the second lenses L2 in the first direction D1 may be less than the length of the first lens L1 in the first direction D1. Each of the plurality of second lenses L2 may be implemented as a hemispherical lens.

The hemispherical second lens L2 may have a circular section when viewed in plan and may have a semicircular section when cut along a cutting line extending in the first direction D1 and when cut along a cutting line extending in the second direction D2. Such a hemispherical second lens L2 may limit the viewing angle in the first and second directions D1 and D2.

As described above, the display device of the present disclosure may be a viewing angle control display device capable of limiting the viewing angle using the hemi-ellipsoidal first lens L1 corresponding to the first lower electrode 171a and the plurality of hemispherical second lenses L2 corresponding to the second lower electrode 171b. The display device of the present disclosure may selectively achieve a wide viewing angle and a narrow viewing angle because a direction in which the first lens L1 limits the viewing angle and a direction in which the second lenses L2 limit the viewing angle are different from each other.

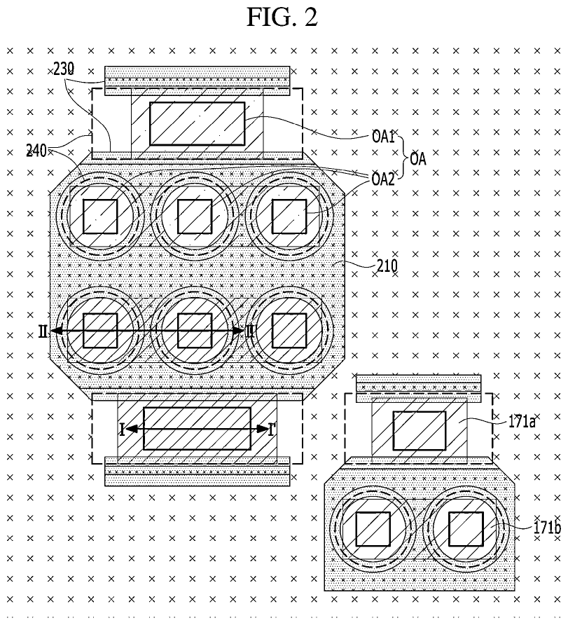

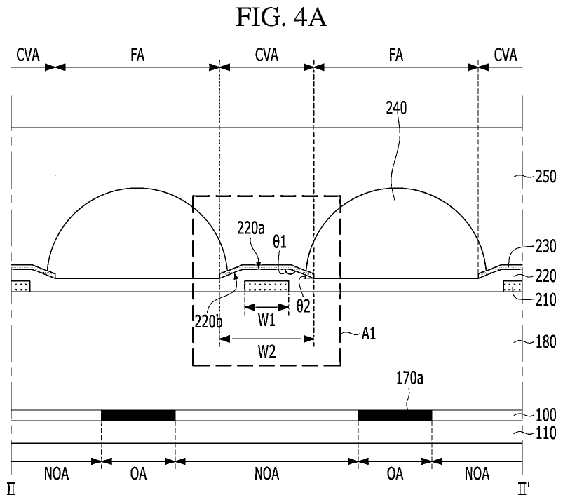

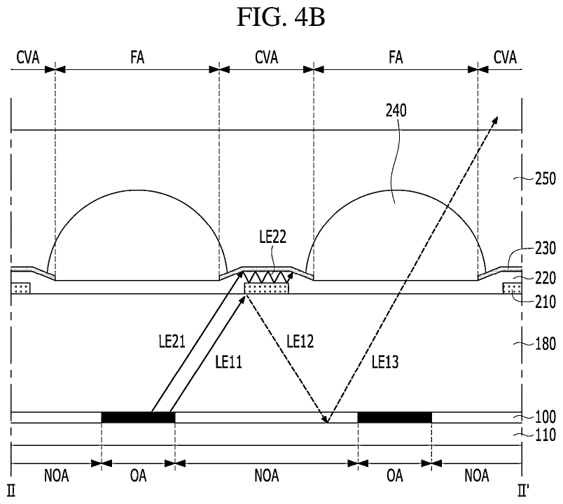

FIG. 2 is a plan view of display devices according to first and second embodiments of the present disclosure. In FIG. 2, since the plan view of the first embodiment and the plan view of the second embodiment are identical to each other, reference numerals of the first embodiment are representatively used. FIG. 3 is a cross-sectional view of a light-emitting array taken along line I-I′ in FIG. 2, and FIGS. 4A and 4B are cross-sectional views of the first embodiment taken along line II-II′ in FIG. 2. FIG. 4B shows a path of light emitted from one light-emitting device in the display device of the present disclosure shown in FIG. 4A.

Referring to FIG. 2, the display device according to the first embodiment of the present disclosure may include a first light-shielding pattern 210 and a second light-shielding pattern 230 provided in the non-open area. The first light-shielding pattern 210 and the second light-shielding pattern 230 may have different widths. In the first embodiment, a second width (W2 in FIG. 4A) of the second light-shielding pattern 230 may be larger than a first width (W1 in FIG. 4A) of the first light-shielding pattern 210.

The first light-shielding pattern 210 may be disposed on the entire surface of a substrate 110 while being spaced apart from the edges of the lenses 240 so as to expose the lenses 240.

The second light-shielding pattern 230 may overlap portions of the edges of the lenses 240 while exposing at least the open areas OA1 and OA2 of the lenses 240. The second light-shielding pattern 230 may be patterned on the substrate 110 so as to be provided in plural. The plurality of second light-shielding patterns 230 may be connected to each other via a connection pattern disposed therebetween.

FIG. 3 is a cross-sectional view of a light-emitting array 100 disposed on the substrate 110 in the display device of the present disclosure. Referring to FIG. 3, the light-emitting array 100 may include components disposed between the substrate 110 and an encapsulation layer 180. A plurality of transistors TFT, a plurality of light-emitting devices 170a respectively connected to the transistors, and an encapsulation layer 180 covering the plurality of light-emitting devices 170a may be disposed on the substrate 110. The light-emitting devices 170a may overlap the open areas OA.

The substrate 110 may be divided into an active area in which a screen is displayed and a non-active area in which a screen is not displayed, and the plurality of sub-pixels (SP1, SP2, and SP3 in FIG. 1) may be repeatedly disposed in the active area. The plurality of sub-pixels SP1, SP2, and SP3 may include emission portions that actually emit light and non-emission portions that are formed around the emission portions and do not emit light. In the present disclosure, the emission portions may overlap the open areas OA provided above the substrate 110. For example, if the substrate 110 is a plastic substrate, the substrate 110 may include polyimide or polyamide.

On the substrate 110, a circuit device, which includes various signal lines such as a data line and a gate line, transistors such as a driving thin-film transistor, a switching thin-film transistor, and a sensing thin-film transistor, and a capacitor, may be provided for each light-emitting device 170a. In the present disclosure, for convenience of description, one transistor TFT, which drives each light-emitting device 170a, is illustrated.

The transistor TFT may include an active layer 37 and a gate electrode 43 overlapping a channel region 35 of the active layer 37 with a gate insulating film 41 interposed therebetween, and may include a source electrode 51 and a drain electrode 53 respectively connected to two opposite sides of the active layer 37.

The active layer 37 may include a source region 31 and a drain region 33 respectively provided at two opposite sides thereof, and may include a channel region 35 disposed between the source region 31 and the drain region 33. Each of the source region 31 and the drain region 33 is formed of a semiconductor material doped with an n-type or p-type dopant. The channel region 35 overlapping the gate electrode 43 may be formed of a semiconductor material not doped with an n-type or p-type dopant.

The gate electrode 43 and the channel region 35 of the active layer 37 may have the same width and may be disposed so as to overlap each other with the gate insulating film 41 interposed therebetween. The gate insulating film 41 may overlap the channel region 35 of the active layer 37 in the same pattern as the gate electrode 43. For example, the gate electrode 43 may take the form of a single layer or multiple layers made of molybdenum (Mo), aluminum (Al), chromium (Cr), gold (Au), titanium (Ti), nickel (Ni), neodymium (Nd), copper (Cu), or an alloy thereof. The gate insulating film 41 may be made of an inorganic insulating material. For example, the gate insulating film 41 may be implemented as a silicon oxide (SiOx) film, a silicon nitride (SiNx) film, a silicon oxynitride (SiOxNy) film, or a multilayered film thereof.

A light-shielding layer 21 on the substrate 110 is disposed under the active layer 37 while overlapping at least the channel region 35 of the active layer 37 of the transistor TFT. The light-shielding layer 21 prevents or at least reduces external light from traveling to the transistor TFT through the substrate 110. For example, the light-shielding layer 21 may be implemented as a single layer made of a metallic material such as molybdenum (Mo), titanium (Ti), aluminum-neodymium (AlNd), aluminum (Al), chromium (Cr), or an alloy thereof, or may be formed in a multilayered structure including the above metallic materials.

A buffer film 111 may be disposed on the light-shielding layer 21 to cover the light-shielding layer 21. For example, the buffer film 111 may take the form of a single layer or multiple layers made of silicon oxide (SiOx) or silicon nitride (SiNx).

An interlayer insulating film 112 may be disposed on the buffer film 111. The interlayer insulating film 112 may include a source contact hole and a drain contact hole respectively exposing the source region 31 and the drain region 33 of the active layer 37, and may cover the gate insulating film 41 and the gate electrode 43. For example, the interlayer insulating film 112 may be made of an inorganic insulating material. For example, the interlayer insulating film 112 may be implemented as a silicon oxide (SiOx) film, a silicon nitride (SiNx) film, a silicon oxynitride (SiOxNy) film, or a multilayered film thereof.

The source electrode 51 and the drain electrode 53 may be disposed in the same layer on the interlayer insulating film 112. The source electrode 51 and the drain electrode 53 are connected to the source region 31 and the drain region 33 of the active layer 37 through the source contact hole and the drain contact hole, respectively. For example, each of the source electrode 51 and the drain electrode 53 may take the form of a single layer made of a metallic material such as molybdenum (Mo), aluminum (Al), chromium (Cr), gold (Au), titanium (Ti), nickel (Ni), neodymium (Nd), copper (Cu), or an alloy thereof, or may be formed in a multilayered structure including the above metallic materials.

A passivation layer 113 may be disposed on the interlayer insulating film 112 to cover the transistor TFT. Accordingly, the transistor TFT may be protected by the passivation layer 113. For example, the passivation layer 113 may be a type of inorganic insulating film, and may be implemented as a silicon oxide (SiOx) film, a silicon nitride (SiNx) film, a silicon oxynitride (SiOxNy) film, or a multilayered film thereof.

A planarization film 114 may be disposed on the passivation layer 113. The planarization film 114 may be formed to a thickness sufficient to provide a substantially planar surface on the uneven surface of the upper portion of the transistor TFT, and may be implemented as an organic insulating film. In a case in which the planarization film 114 also functions to protect the transistor TFT, the passivation layer 113 may be omitted. For example, the planarization film 114 may be a type of organic insulating film. For example, the planarization film 114 may be implemented as a photo acryl film, a polyimide film, a benzocyclobutene resin film, or an acrylate film, or, in some cases, may be implemented as a multilayered film thereof.

A light-emitting device 170a, which includes a first lower electrode 171a, an intermediate layer 173, and an upper electrode 175, may be disposed on the planarization film 114. The light-emitting device 170a may be driven in such a manner that the intermediate layer 173 emits light as an electric field is formed between the first lower electrode 171a and the upper electrode 175.

The first lower electrode 171a may be formed in a multilayered structure including a transparent conductive film and an opaque conductive film having high reflection efficiency. The transparent conductive film of the first lower electrode 171a may be formed of a material having a relatively large work function, e.g., indium-tin-oxide (ITO) or indium-zinc-oxide (IZO), and the opaque conductive film thereof may be formed in a single-layered or multilayered structure including a material selected from the group comprising silver (Ag), aluminum (Al), copper (Cu), molybdenum (Mo), titanium (Ti), nickel (Ni), chromium (Cr), tungsten (W), and alloys thereof. For example, the first lower electrode 171a may be formed in a structure in which a transparent conductive film, an opaque conductive film, and a transparent conductive film are sequentially stacked or may be formed in a structure in which a transparent conductive film and an opaque conductive film are sequentially stacked.

A bank 115 may be disposed on the entire surface of the planarization film 114 so as to cover the edge of the first lower electrode 171a. The bank 115 may define an open area OA to expose the light-emitting device 170a. In some cases, the bank 115 may include a light-absorbing material. In this case, the bank 115 may include a black dye. Accordingly, the display device of the present disclosure may prevent or at least reduce optical interference and light leakage between adjacent sub-pixels.

The intermediate layer 173 may be disposed on the first and second lower electrodes 171a and 171b and the bank 115 over the entire area of the substrate 110. In detail, the intermediate layer 173 may be an organic layer having a single-stack structure constituted by multiple layers including a hole injection layer, a hole transport layer, an emission layer, an electron transport layer, and an electron injection layer. In some cases, the intermediate layer 173 may be formed in a tandem structure including multiple stacks (first stack and second stack), which include a first emission layer and a second emission layer, respectively, and a charge generation layer disposed between the stacks. The tandem structure is not limited to the illustrated 2-stack structure, but may be a multi-stack structure including three or more stacks. The first and second emission layers in the multiple stacks may be emission layers emitting light of the same color among red light, green light, and blue light, and may be patterned in each of the plurality of sub-pixels SP1, SP2, and SP3.

The upper electrode 175 disposed on the intermediate layer 173 may be formed on the entire surface of the substrate 110 through a common mask. For example, the upper electrode 175 may be made of a transparent conductive material such as indium-tin-oxide (ITO) or indium-zinc-oxide (IZO), or may be made of silver (Ag), aluminum (Al), magnesium (Mg), calcium (Ca), or an alloy thereof and may be formed to be thin enough to transmit light.

The encapsulation layer 180 may be disposed on the upper electrode 175 so as to cover the entireties of the active area and the non-active area on the substrate 110. The encapsulation layer 180 prevents or at least reduces oxygen and moisture from entering the light-emitting device 170a, thereby improving the lifespan of the light-emitting display device. In an example, the encapsulation layer 180 may be formed in a structure in which one or more pairs of an inorganic encapsulation film and an organic encapsulation film are stacked.

Referring to FIG. 4A, the display device of the present disclosure may include a first insulating layer 220 disposed on the encapsulation layer 180, lenses 240 disposed on the first insulating layer 220 so as to respectively correspond to the plurality of light-emitting devices 170a, first light-shielding patterns 210 disposed between the substrate 110 and the first insulating layer 220 so as to respectively correspond to the plurality of light-emitting devices 170a, and second light-shielding patterns 230 disposed on the first insulating layer 220 so as to overlap the first light-shielding patterns 210. In the display device of the present disclosure, an edge portion thereof around the central portion may have a first angle θ1 with respect to a central portion of the second light-shielding pattern 230.

The first insulating layer 220 may be disposed on the entire area of the encapsulation layer 180. The first insulating layer 220 according to the first embodiment may include convex areas CVA formed corresponding to the non-open areas NOA on the substrate 110. The convex areas CVA may be formed along the edges of the lenses 240 within the non-open areas NOA. The convex areas CVA may be portions protruding relative to flat areas FA in a direction away from the substrate 110. Portions of the first insulating layer 220 except for the convex areas CVA may be the flat areas FA. In this case, the first insulating layer 220 may be formed so as to include the flat areas FA and the convex areas CVA through a process using a half-tone mask.

The convex area CVA of the first insulating layer 220 may be formed along the edge of each of the lenses 240. In some cases, the edge of the convex area CVA of the first insulating layer 220 may partially overlap the edge of each of the lenses 240. That is, the convex area CVA of the first insulating layer 220 may be disposed along the edge of the open area OA. The convex area CVA of the first insulating layer 220 may include an upper surface 220a parallel to the flat area FA and a side surface 220b inclined from the upper surface 220a toward the substrate 110. In the convex area CVA of the first insulating layer 220, the first angle θ1 formed between the upper surface 220a and the side surface 220b may be equal to or greater than 90° and less than 180°. A second angle θ2 formed by the side surface 220b of the convex area CVA with respect to the substrate 110 may be an acute angle. Here, if a vertical spacing distance between the surface of the flat area FA and the upper surface 220a of the convex area CVA is about 3 μm according to a process using a half-tone mask, the second angle θ2 formed by the side surface 220b of the convex area CVA with respect to the substrate 110 may be about 70°. The second light-shielding pattern 230 may be disposed on the convex area CVA of the first insulating layer 220, and the first light-shielding pattern 210 may be disposed under the convex area CVA of the first insulating layer 220. The convex area CVA may make the second light-shielding pattern 230 curved.

The flat area FA of the first insulating layer 220 may be a portion of the first insulating layer 220 except for the convex area CVA. The flat area FA may be connected to the side surface 220b of the convex area CVA, and the lens 240 may be disposed on the flat area FA so as to respectively correspond to the plurality of light-emitting devices 170a. In other words, the lens 240 may be disposed on the flat area FA of the first insulating layer 220 that overlaps each of the open areas OA. The lens 240 may extend beyond the flat area FA of the first insulating layer 220 to overlap a portion of the convex area CVA outside the flat area FA.

The first light-shielding pattern 210 and the second light-shielding pattern 230 may be disposed with the convex area CVA of the first insulating layer 220 interposed therebetween. The first light-shielding pattern 210 and the second light-shielding pattern 230 may be made of different materials. In addition, the first light-shielding pattern 210 and the second light-shielding pattern 230 may have different reflectances. The first light-shielding pattern 210 and the second light-shielding pattern 230 may have different widths, and any one thereof may be formed such that the edge portion thereof is inclined with respect to the central portion thereof. In the display device according to the first embodiment, the second width W2 of the second light-shielding pattern 230 may be larger than the first width W1 of the first light-shielding pattern 210, and the second light-shielding pattern 230 may be formed such that the edge portion thereof is inclined with respect to the central portion thereof.

The first light-shielding pattern 210 may be disposed on the area of the encapsulation layer 180 except for the area thereof corresponding to each of the open areas OA. The first light-shielding pattern 210 may overlap the upper surface 220a of the convex area CVA between the flat areas FA of the first insulating layer 220. In addition, the first light-shielding pattern 210 may expose at least a portion of the second light-shielding pattern 230 overlapping the side surface 220b of the first insulating layer 220 to the substrate 110. In addition, the first light-shielding pattern 210 may also expose a portion of the second light-shielding pattern 230 overlapping the edge of the upper surface 220a connected to the side surface 220b of the first insulating layer 220 to the substrate 110 in consideration of an incidence angle of light from the light-emitting device. In other words, the first light-shielding pattern 210 may partially overlap the upper surface 220a of the first insulating layer 220.

The first light-shielding pattern 210 may include a light-absorbing material. For example, the first light-shielding pattern 210 may include a black dye. The first light-shielding pattern 210 may prevent or at least reduce optical interference and light leakage between adjacent sub-pixels. Although the first light-shielding pattern 210 includes a light-absorbing material, the same may have a certain amount of reflectance. The first light-shielding pattern 210 including a typical light-absorbing material may have a reflectance of about 4.6%.

The second light-shielding pattern 230 may be disposed on the convex area CVA of the first insulating layer 220. That is, the second light-shielding pattern 230 may be disposed along the edge of each of the lenses 240. The second light-shielding pattern 230 may be formed in a shape corresponding to the shape of the upper surface 220a and the side surface 220b of the convex area CVA of the first insulating layer 220. The second light-shielding pattern 230 may be divided into a central portion that is in contact with the upper surface 220a of the convex area CVA of the first insulating layer 220 and an edge portion that is in contact with the side surface 220b of the convex area CVA of the first insulating layer 220, and the edge portion of the second light-shielding pattern 230 may be inclined with respect to the central portion thereof according to the shape of the convex area CVA of the first insulating layer 220. In other words, the edge portion of the second light-shielding pattern 230 may form the first angle θ1 with the central portion thereof. Here, the first angle θ1 may be equal to or greater than 90° and less than 180° according to the shape of the convex area CVA of the first insulating layer 220. In addition, the central portion of the second light-shielding pattern 230 that is in contact with the upper surface 220a of the convex area CVA of the first insulating layer 220 may overlap the first light-shielding pattern 210, and the edge portion of the second light-shielding pattern 230 that is in contact with the side surface 220b of the convex area CVA of the first insulating layer 220 may be exposed to the substrate 110 from the first light-shielding pattern 210. Accordingly, light that is emitted from the light-emitting device 170a and travels to an area between the lenses 240 may be introduced into the portion of the second light-shielding pattern 230 that is exposed from the first light-shielding pattern 210. The introduced light may be reflected to an area between the first light-shielding pattern 210 and the second light-shielding pattern 230 by the inclined edge portion of the second light-shielding pattern 230. In addition, the introduced light may be reflected at an acute angle by the inclined edge portion of the second light-shielding pattern 230, and then may be re-reflected by metallic components of the light-emitting device 170a. The re-reflected light may travel to an area far away from the lens adjacent to the light-emitting device 170a, and thus is less likely to reach lenses that do not correspond to the light-emitting device 170a. Accordingly, among the light that is emitted from the light-emitting device 170a and travels to an area between the lenses 240, the amount of light reaching lenses that do not correspond to the light-emitting device 170a may be greatly reduced.

The second light-shielding pattern 230 may be made of metal. For example, the second light-shielding pattern 230 may be a touch electrode. In this case, the second light-shielding pattern 230 may include a plurality of transmitting electrodes and a plurality of receiving electrodes crossing each other, and may detect a touch from a variation in capacitance between the plurality of transmitting electrodes and the plurality of receiving electrodes. Referring to FIG. 2, if the illustrated second light-shielding patterns 230 are touch electrodes, each of the second light-shielding patterns 230 may be one of a transmitting electrode and a receiving electrode, and connection electrodes electrically connecting the transmitting electrodes and the receiving electrodes to each other may be further included. The second light-shielding pattern 230 made of a typical metallic material may have a reflectance of about 50%.

Referring to FIG. 4B, light emitted from the light-emitting device 170a on the substrate 110 may pass through the open area OA, and a portion of the light may travel to the non-open area NOA. The light that is emitted from the light-emitting device 170a and travels to the non-open area NOA may reach the first light-shielding pattern 210 and the second light-shielding pattern 230 between the lenses 240. Referring to LE11, LE12, and LE13 in FIG. 4B, the light LE11 that is emitted from the light-emitting device 170a and reaches the first light-shielding pattern 210 may be partially absorbed in the first light-shielding pattern 210, and the remaining portion of the light LE11 may be reflected (LE12) to the light-emitting array 100 in which the light-emitting device 170a is provided. Then, the reflected light LE12 may be re-reflected (LE13) to another lens that does not correspond to the light-emitting device 170a by the component such as the lower electrode or the upper electrode of the light-emitting device 170a. In this way, a portion of the light that has reached the first light-shielding pattern 210 having a planar shape may travel to another lens that does not correspond to the light-emitting device 170a through reflection and re-reflection. Therefore, light leakage may occur. However, according to the present disclosure, the first light-shielding pattern 210 is formed to have a smaller width than the second light-shielding pattern 230, and the relatively narrow first light-shielding pattern 210 is disposed between the lenses 240. In this way, the planar reflecting element may be minimized or at least reduced in width.

In addition, referring to FIG. 4B, due to the second light-shielding pattern 230 including the central portion and the edge portion inclined with respect to the central portion, the present disclosure may greatly reduce reflection and re-reflection of the light emitted from the light-emitting device 170a toward another lens that does not correspond to the light-emitting device 170a. For example, light LE21 that is emitted from the light-emitting device 170a and reaches the portion of the second light-shielding pattern 230 exposed from the first light-shielding pattern 210 may be partially absorbed in the second light-shielding pattern 230, and the remaining portion of the light LE21 may be reflected from the second light-shielding pattern 230. In this case, the light may be reflected to the first light-shielding pattern 210 due to the inclined shape of the second light-shielding pattern 230, and may undergo repeated re-reflection and absorption (LE22) between the first light-shielding pattern 210 and the second light-shielding pattern 230. In this way, the light LE21 that has reached the portion of the second light-shielding pattern 230 that is in contact with the side surface 220b of the convex area CVA of the first insulating layer 220 may be trapped between the first light-shielding pattern 210 and the second light-shielding pattern 230. Accordingly, it is possible to prevent or at least reduce light from traveling to another lens that does not correspond to the light-emitting device 170a, thereby preventing or at least reducing light leakage.

A planarization layer 250 may be disposed on the first insulating layer 220 provided thereon with the second light-shielding pattern 230 and the lens 240. The planarization layer 250 may provide a substantially planar surface on the surface of the first insulating layer 220 and the uneven surfaces of the second light-shielding pattern 230 and the lens 240 disposed on the first insulating layer 220. For example, the planarization layer 250 may be made of a type of organic insulating material.

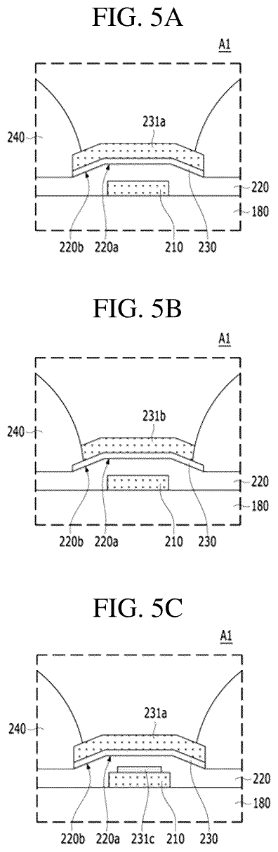

FIGS. 5A, 5B, and 5C are views showing various modified examples of portion A1 in FIG. 4A in accordance with one embodiment.

Referring to FIGS. 5A to 5C, a third light-shielding pattern may be disposed on the second light-shielding pattern 230, may be disposed on the first light-shielding pattern 210, or may be disposed both on the second light-shielding pattern 230 and on the first light-shielding pattern 210.

Referring to FIG. 5A, a third light-shielding pattern 231a may be disposed on the second light-shielding pattern 230. The third light-shielding pattern 231a may cover the entire area of the upper surface of the second light-shielding pattern 230. In this case, the edge of the third light-shielding pattern 231a may be covered by the lenses 240. The third light-shielding pattern 231a may include the same material as the first light-shielding pattern 210.

Referring to FIG. 5B, a third light-shielding pattern 231b may be disposed on a portion of the second light-shielding pattern 230. In this case, the side surface of the third light-shielding pattern 231b may be in contact with the lenses 240. The third light-shielding pattern 231b may include the same material as the first light-shielding pattern 210.

Referring to FIG. 5C, a third light-shielding pattern 231a may be disposed on the second light-shielding pattern 230, and a fourth light-shielding pattern 231c may be disposed on the first light-shielding pattern 210. The third light-shielding pattern 231a may cover the entire area of the upper surface of the second light-shielding pattern 230 and may include the same material as the first light-shielding pattern 210. The fourth light-shielding pattern 231c may be disposed on a portion of the first light-shielding pattern 210 and may include a metal. If the first light-shielding pattern 210 is a touch electrode, the fourth light-shielding pattern 231c may be a connection electrode interconnecting the plurality of first light-shielding patterns 210. In this case, the fourth light-shielding pattern 231c may be electrically connected to the first light-shielding pattern 210.

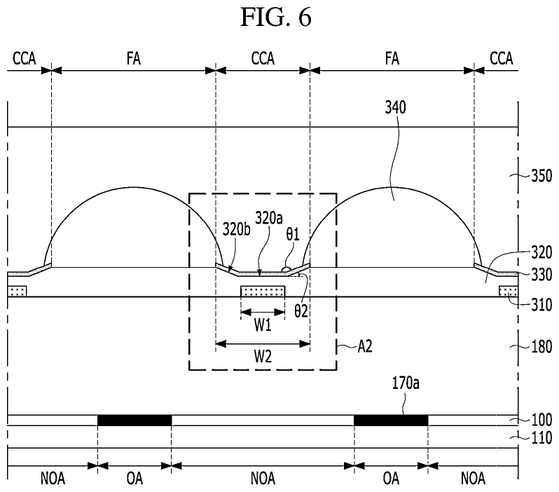

FIG. 6 is a cross-sectional view of the second embodiment taken along line II-II′ in FIG. 2. Hereinafter, description of the same configuration as that of the first embodiment will be omitted.

Referring to FIG. 6, a first insulating layer 320 according to the second embodiment may include concave areas CCA formed corresponding to the non-open areas NOA. The concave areas CCA may be formed along the edges of lenses 340. The concave areas CCA may be portions depressed relative to flat areas FA toward the substrate 110. Portions of the first insulating layer 320 except for the concave areas CCA may be the flat areas FA.

The concave area CCA of the first insulating layer 320 may partially overlap the edge of each of the lenses 340. The concave area CCA may include a bottom surface 320a parallel to the flat area FA and a side surface 320b formed between the bottom surface 320a and the surface of the flat area FA adjacent thereto. The bottom surface 320a and the side surface 320b of the concave area CCA may form a first angle θ1 therebetween. The first angle θ1 may be equal to or greater than 90° and less than 180°. In addition, the side surface 320b of the concave area CCA may form a second angle θ2 with respect to the substrate 110. The second angle θ2 may be an acute angle. A second light-shielding pattern 330 may disposed on the concave area CCA of the first insulating layer 320, and a first light-shielding pattern 310 may be disposed under the concave area CCA of the first insulating layer 320. The concave area CCA may make the second light-shielding pattern 330 curved.

The first light-shielding pattern 310 and the second light-shielding pattern 330 may be disposed with each of the concave areas CCA of the first insulating layer 320 interposed therebetween. The first light-shielding pattern 310 and the second light-shielding pattern 330 may be made of different materials. In addition, the first light-shielding pattern 310 and the second light-shielding pattern 330 may have different reflectances. The first light-shielding pattern 310 and the second light-shielding pattern 330 may have different widths, and any one thereof may be formed such that the edge portion thereof is inclined with respect to the central portion thereof. In the display device according to the second embodiment, the second width W2 of the second light-shielding pattern 330 may be larger than the first width W1 of the first light-shielding pattern 310, and the edge portion of the second light-shielding pattern 330 has a relatively large width may be formed to be inclined.

The first light-shielding pattern 310 may be disposed on the area of the encapsulation layer 180 except for the area thereof corresponding to each of the open areas OA. The first light-shielding pattern 310 may overlap the bottom surface 320a of the concave area CCA between the flat areas FA of the first insulating layer 320. That is, the first light-shielding pattern 310 may expose at least a portion of the second light-shielding pattern 330 overlapping the side surface 320b of the first insulating layer 320 to the substrate 110.

The second light-shielding pattern 330 may be disposed on the concave area CCV of the first insulating layer 320. That is, the second light-shielding pattern 330 may be disposed along the edge of each of the lenses 340. The second light-shielding pattern 330 may be formed in a shape corresponding to the shape of the bottom surface 320a and the side surface 320b of the concave area CCA of the first insulating layer 320. The second light-shielding pattern 330 may be divided into a central portion that is in contact with the bottom surface 320a of the concave area CCA of the first insulating layer 320 and an edge portion that is in contact with the side surface 320b of the concave area CCA of the first insulating layer 320, and the edge portion of the second light-shielding pattern 330 may be inclined with respect to the central portion thereof according to the shape of the concave area CCA of the first insulating layer 320. In other words, the edge portion of the second light-shielding pattern 330 may be inclined at a predetermined angle with respect to the substrate 110, i.e., the second angle θ2 defined by the concave area CCA of the first insulating layer 320. In addition, the central portion of the second light-shielding pattern 330 that is in contact with the bottom surface 320a of the concave area CCA of the first insulating layer 320 may overlap the first light-shielding pattern 310. In other words, the edge portion of the second light-shielding pattern 330 that is in contact with the side surface 320b of the concave area CCA of the first insulating layer 320 may be exposed to the substrate 110 from the first light-shielding pattern 310. Accordingly, light that is emitted from the light-emitting device 170a and travels to an area between the lenses 340 may be introduced into the portion of the second light-shielding pattern 330 that is exposed from the first light-shielding pattern 310, and the introduced light may be reflected at an acute angle by the inclined edge portion of the second light-shielding pattern 330. Accordingly, the amount of light reaching another lens that does not correspond to the light-emitting device 170a due to re-reflection by components of the light-emitting device 170a may be reduced.

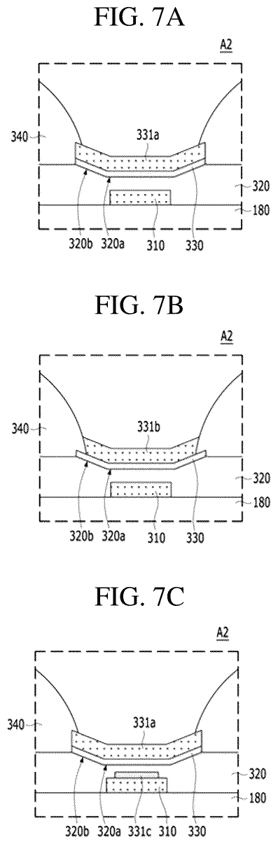

FIGS. 7A, 7B, and 7C are views showing various modified examples of portion A2 in FIG. 6 in accordance with one embodiment.

Referring to FIGS. 7A to 7C, a third light-shielding pattern may be disposed on the second light-shielding pattern 330, may be disposed on the first light-shielding pattern 310, or may be disposed both on the second light-shielding pattern 330 and on the first light-shielding pattern 310.

Referring to FIG. 7A, a third light-shielding pattern 331a may be disposed on the second light-shielding pattern 330. The third light-shielding pattern 331a may cover the entire area of the upper surface of the second light-shielding pattern 330. In this case, the edge of the third light-shielding pattern 331a may be covered by the lenses 340. The third light-shielding pattern 331a may include the same material as the first light-shielding pattern 310.

Referring to FIG. 7B, a third light-shielding pattern 331b may be disposed on a portion of the second light-shielding pattern 330. In this case, the side surface of the third light-shielding pattern 331b may be in contact with the lenses 340. The third light-shielding pattern 331b may include the same material as the first light-shielding pattern 310.

Referring to FIG. 7C, a third light-shielding pattern 331a may be disposed on the second light-shielding pattern 330, and a fourth light-shielding pattern 331c may be disposed on the first light-shielding pattern 310. The third light-shielding pattern 331a may cover the entire area of the upper surface of the second light-shielding pattern 330 and may include the same material as the first light-shielding pattern 310. The fourth light-shielding pattern 331c may be disposed on a portion of the first light-shielding pattern 310 and may include a metal. If the first light-shielding pattern 310 is a touch electrode, the fourth light-shielding pattern 331c may be a connection electrode interconnecting the plurality of first light-shielding patterns 310. In this case, the fourth light-shielding pattern 331c may be electrically connected to the first light-shielding pattern 310.

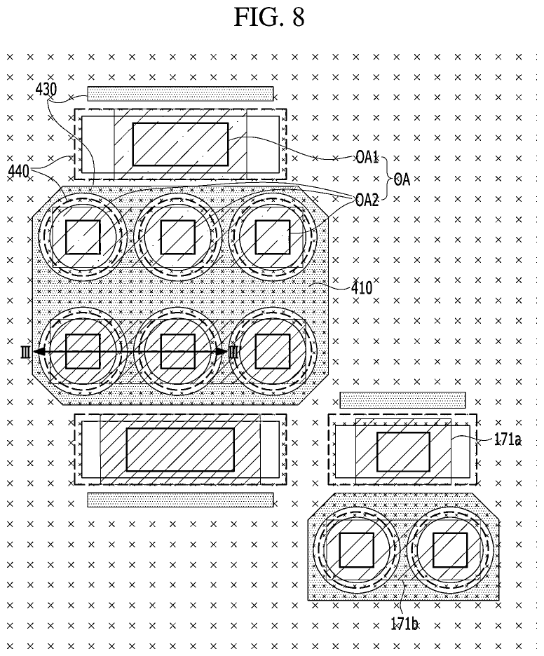

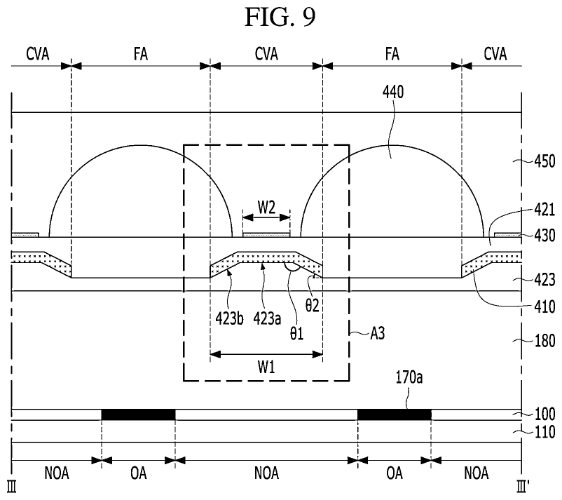

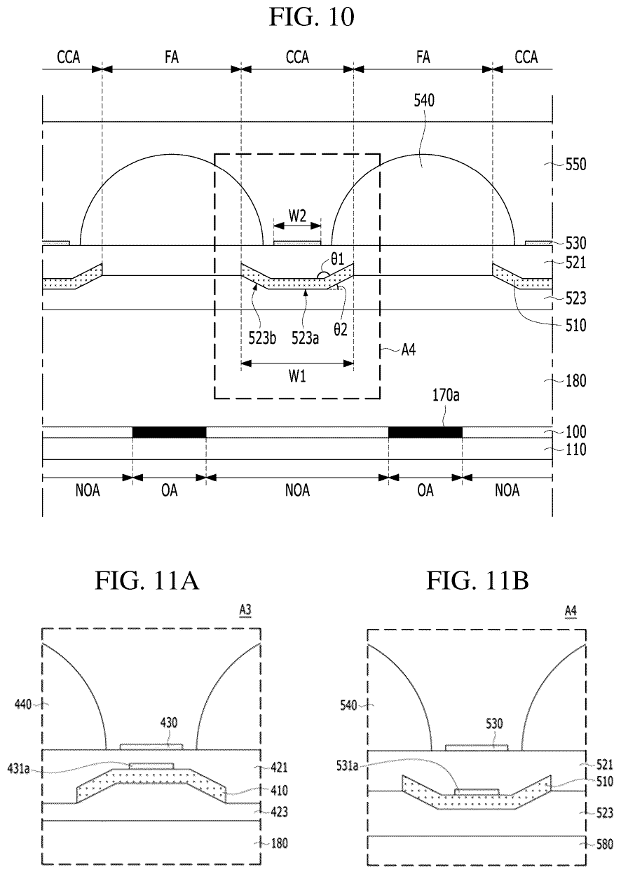

FIG. 8 is a plan view of display devices according to third and fourth embodiments of the present disclosure. In FIG. 8, since the plan view of the third embodiment and the plan view of the fourth embodiment are identical to each other, reference numerals of the third embodiment are representatively used. FIG. 9 is a cross-sectional view of the third embodiment taken along line III-III′ in FIG. 8, and FIG. 10 is a cross-sectional view of the fourth embodiment taken along line III-III′ in FIG. 8.

Referring to FIG. 8, the display device according to the third embodiment of the present disclosure may include a first light-shielding pattern 410 and a second light-shielding pattern 430 provided in the non-open area NOA. The first light-shielding pattern 410 and the second light-shielding pattern 430 may have different widths. In the third embodiment, the first width W1 of the first light-shielding pattern 410 may be larger than the second width W2 of the second light-shielding pattern 430.

In the third embodiment, the first light-shielding pattern 410 may overlap portions of the edges of the lenses 440 while exposing at least the open areas OA overlapping the lenses 440. The first light-shielding pattern 410 may be disposed on the area of the substrate 110 except for the open areas.

The second light-shielding pattern 430 may be spaced apart from the edges of the lenses 440 so as to exposes the lenses 440. The second light-shielding pattern 430 may be patterned on the substrate 110 so as to be provided in plural. The plurality of second light-shielding patterns 430 may be connected to each other via a connection pattern disposed therebetween.

FIG. 9 is a cross-sectional view of the third embodiment taken along line III-III′ in FIG. 8.

Referring to FIG. 9, in the third embodiment of the present disclosure, a second insulating layer 423 may be disposed between the encapsulation layer 180 and a first insulating layer 421. In addition, the first light-shielding pattern 410 according to the third embodiment may be disposed between the first insulating layer 421 and the second insulating layer 423. Accordingly, in the third embodiment of the present disclosure, the second insulating layer 423 may make the first light-shielding pattern 410 curved.

The first and second insulating layers 421 and 423 may be disposed on the entire area of the encapsulation layer 180. The second insulating layer 423 according to the third embodiment may include convex areas CVA formed corresponding to the non-open areas NOA on the substrate 110. The convex areas CVA may be formed along the edges of the lenses 440 within the non-open areas NOA. The convex areas CVA may be portions protruding relative to flat areas FA in a direction away from the substrate 110. Portions of the second insulating layer 423 except for the convex areas CVA may be the flat areas FA.

The convex area CVA of the second insulating layer 423 may be formed along the edge of each of the lenses 440. In some cases, the edge of the convex area CVA of the second insulating layer 423 may partially overlap the edge of each of the lenses 440. The convex area CVA of the second insulating layer 423 may include an upper surface 423a parallel to the flat area FA and a side surface 423b inclined from the upper surface 423a toward the substrate 110. In the convex area CVA, a first angle θ1 formed between the upper surface 423a and the side surface 423b may be equal to or greater than 90° and less than 180°. A second angle θ2 formed by the side surface 423b of the convex area CVA with respect to the substrate 110 may be an acute angle. The first light-shielding pattern 410 may be disposed on the convex area CVA of the second insulating layer 423.

The first insulating layer 421 may be disposed on the second insulating layer 423 and the first light-shielding pattern 410. The lens 440 may be disposed on the area of the first insulating layer 421 overlapping the flat area FA of the second insulating layer 423, and the second light-shielding pattern 430 may be disposed on the area of the first insulating layer 421 overlapping the convex area CVA of the second insulating layer 423. The lens 440 may extend beyond the flat area FA of the second insulating layer 423 to overlap a portion of the convex area CVA outside the flat area FA.

The first light-shielding pattern 410 and the second light-shielding pattern 430 may be disposed on the convex area CVA with the first insulating layer 421 interposed therebetween. The first light-shielding pattern 410 and the second light-shielding pattern 430 may be made of different materials. In addition, the first light-shielding pattern 410 and the second light-shielding pattern 430 may have different reflectances. In the display device according to the third embodiment, the first width W1 of the first light-shielding pattern 410 may be larger than the second width W2 of the second light-shielding pattern 430, and the edge portion of the first light-shielding pattern 410 having a relatively large width may be formed to be inclined.

The first light-shielding pattern 410 may be disposed on the convex area CVA of the second insulating layer 423. That is, the first light-shielding pattern 410 may be disposed along the edge of each of the lenses 440. The first light-shielding pattern 410 may be formed in a shape corresponding to the shape of the upper surface 423a and the side surface 423b of the convex area CVA of the second insulating layer 423. The first light-shielding pattern 410 may be divided into a central portion that is in contact with the upper surface 423a of the convex area CVA of the second insulating layer 423 and an edge portion that is in contact with the side surface 423b of the convex area CVA of the second insulating layer 423, and the edge portion of the first light-shielding pattern 410 may be inclined with respect to the central portion thereof according to the shape of the convex area CVA of the second insulating layer 423. In other words, the edge portion of the first light-shielding pattern 410 may be inclined at a predetermined angle with respect to the substrate 110, i.e., the second angle θ2 defined by the convex area CVA of the second insulating layer 423. In addition, the central portion of the first light-shielding pattern 410 that is in contact with the upper surface 423a of the convex area CVA of the second insulating layer 423 may overlap the second light-shielding pattern 430, and the edge portion of the first light-shielding pattern 410 that is in contact with the side surface 423b of the convex area CVA of the second insulating layer 423 may be exposed to a side opposite the substrate 110 from the second light-shielding pattern 430. Accordingly, light that is emitted from the light-emitting device 170a and travels to an area between the lenses 440 may be reflected at an acute angle by the inclined edge portion of the first light-shielding pattern 410. Accordingly, the amount of light reaching another lens that does not correspond to the light-emitting device 170a due to re-reflection by reflective components of the light-emitting device 170a may be reduced. Here, the reflective components of the light-emitting device 170a may include the lower electrode (171a in FIG. 3) and the upper electrode (175 in FIG. 3).

The second light-shielding pattern 430 may be disposed on the first insulating layer 421. The second light-shielding pattern 430 may overlap the upper surface 423a of the convex area CVA between the flat areas FA of the second insulating layer 423. Because the second light-shielding pattern 430 is made of a metal, the second light-shielding pattern 430 disposed between the lenses 440 may be formed to have as small a width as possible in order to minimize or at least reduce interference between metals. However, the second light-shielding pattern 430 according to the third embodiment of the present disclosure is not limited thereto. In some cases, the second light-shielding pattern 430 may overlap the lenses 440 adjacent thereto.

FIG. 10 is a cross-sectional view of the fourth embodiment taken along line III-III′ in FIG. 8.

Referring to FIG. 10, a second insulating layer 523 according to the fourth embodiment may include concave areas CCA formed corresponding to the non-open areas NOA. The concave areas CCA may be formed along the edges of lenses 540. The concave areas CCA may be portions depressed relative to flat areas FA toward the substrate 110. Portions of the second insulating layer 523 except for the concave areas CCA may be the flat areas FA.

The concave area CCA of the second insulating layer 523 may partially overlap the edge of each of the lenses 540. The concave area CCA may include a bottom surface 523a parallel to the flat area FA and a side surface 523b formed between the bottom surface 523a and the surface of the flat area FA adjacent thereto. The side surface 523b and the bottom surface 523a of the concave area CCA may form a first angle θ1 therebetween. The first angle θ1 may be equal to or greater than 90° and less than 180°. The side surface 523b of the concave area CCA may form a second angle θ2 with respect to the substrate 110. The second angle θ2 of the side surface 523b of the concave area CCA may be an acute angle. A first light-shielding pattern 510 may disposed on the concave area CCA of the second insulating layer 523. The concave area CCA may make the first light-shielding pattern 510 curved.

The first light-shielding pattern 510 and a second light-shielding pattern 530 may be disposed on each of the concave areas CCA with a first insulating layer 521 interposed therebetween. The first light-shielding pattern 510 and the second light-shielding pattern 530 may be made of different materials. In addition, the first light-shielding pattern 510 and the second light-shielding pattern 530 may have different reflectances. In the display device according to the fourth embodiment, the first width W1 of the first light-shielding pattern 510 may be larger than the second width W2 of the second light-shielding pattern 530, and the edge portion of the first light-shielding pattern 510 having a relatively large width may be formed to be inclined.

The first light-shielding pattern 510 may be disposed on the concave area CCA of the second insulating layer 523. That is, the first light-shielding pattern 510 may be disposed along the edge of each of the lenses 540. In addition, the first light-shielding pattern 510 may be disposed on the area of the second insulating layer 523 except for the predetermined area corresponding to the flat area FA. The first light-shielding pattern 510 may be formed in a shape corresponding to the shape of the bottom surface 523a and the side surface 523b of the concave area CCA of the second insulating layer 523. The first light-shielding pattern 510 may be divided into a central portion that is in contact with the bottom surface 523a of the concave area CCA of the second insulating layer 523 and an edge portion that is in contact with the side surface 523b of the concave area CCA of the second insulating layer 523, and the edge portion of the first light-shielding pattern 510 may be inclined with respect to the central portion thereof according to the shape of the concave area CCA of the second insulating layer 523. In other words, the edge portion of the first light-shielding pattern 510 may be inclined at a predetermined angle with respect to the substrate 110, i.e., the second angle θ2 defined by the concave area CCA of the second insulating layer 523. In addition, the central portion of the first light-shielding pattern 510 that is in contact with the bottom surface 523a of the concave area CCA of the second insulating layer 523 may overlap the second light-shielding pattern 530, and the edge portion of the first light-shielding pattern 510 that is in contact with the side surface 523b of the concave area CCA of the second insulating layer 523 may be exposed to a side opposite the substrate 110 from the second light-shielding pattern 530. Accordingly, light that is emitted from the light-emitting device 170a and travels to an area between the lenses 540 may be reflected at an acute angle by the inclined edge portion of the first light-shielding pattern 510. Accordingly, the amount of light reaching another lens that does not correspond to the light-emitting device 170a due to re-reflection by reflective components of the light-emitting device 170a may be reduced.

The second light-shielding pattern 530 may be disposed on the first insulating layer 521. The second light-shielding pattern 530 may overlap the bottom surface 523a of the concave area CCA between the flat areas FA of the second insulating layer 523. Because the second light-shielding pattern 530 is made of a metal, the second light-shielding pattern 530 disposed between the flat areas FA, i.e., between the lenses 540, may be formed to have as small a width as possible in order to minimize or at least reduce interference between metals. However, the second light-shielding pattern 530 according to the fourth embodiment of the present disclosure is not limited thereto. In some cases, the second light-shielding pattern 530 may overlap the lenses 540 adjacent thereto.

FIGS. 11A and 11B are views showing modified examples of portion A3 in FIG. 9 and portion A4 in FIG. 10 in accordance with one embodiment.

Referring to FIGS. 11A to 11B, a third light-shielding pattern 431a or 531a may be disposed on the first light-shielding pattern 410 or 510. Although not shown, a separate light-shielding pattern including the same material as the first light-shielding pattern 410 or 510 may be disposed on the second light-shielding pattern 430 or 530.

Referring to FIG. 11A, the third light-shielding pattern 431a may be disposed on the first light-shielding pattern 410. The third light-shielding pattern 431a may be disposed on a portion of the first light-shielding pattern 410 and may include a metal. If the first light-shielding pattern 410 is a touch electrode, the third light-shielding pattern 431a may be a connection electrode interconnecting the plurality of first light-shielding patterns 410. In this case, the third light-shielding pattern 431a may be electrically connected to the first light-shielding pattern 410.

Referring to FIG. 11B, the third light-shielding pattern 531a may be disposed on the first light-shielding pattern 510. The third light-shielding pattern 531a may be disposed on a portion of the first light-shielding pattern 510 and may include a metal. If the first light-shielding pattern 510 is a touch electrode, the third light-shielding pattern 531a may be a connection electrode interconnecting the plurality of first light-shielding patterns 510. In this case, the third light-shielding pattern 531a may be electrically connected to the first light-shielding pattern 510.

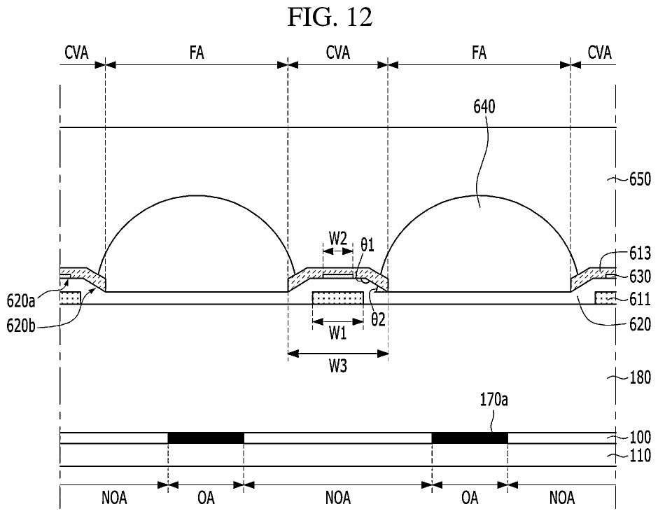

FIG. 12 is a cross-sectional view of a display device according to a fifth embodiment of the present disclosure.

In the display device according to the fifth embodiment of the present disclosure, first light-shielding patterns 611 corresponding to the non-open areas NOA may be disposed on the encapsulation layer 180, a first insulating layer 620 may be disposed on the first light-shielding patterns 611 over the substrate 110, second light-shielding patterns 630 and third light-shielding patterns 613 may be disposed on convex areas CVA of the first insulating layer 620, and lenses 640 may be disposed on flat areas FA of the first insulating layer 620 that overlap the open areas OA.

The first insulating layer 620 may be disposed on the entire area of the encapsulation layer 180. The first insulating layer 620 according to the fifth embodiment may include convex areas CVA formed corresponding to the non-open areas NOA on the substrate 110. The convex areas CVA may be formed along the edges of the lenses 640 within the non-open areas NOA. Portions of the first insulating layer 620 except for the convex areas CVA may be flat areas FA.

The convex area CVA of the first insulating layer 620 may be formed along the edge of each of the lenses 640. The convex area CVA of the first insulating layer 620 may be disposed along the edge of the open area OA. The convex area CVA of the first insulating layer 620 may include an upper surface 620a parallel to the flat area FA and a side surface 620b inclined from the upper surface 620a toward the substrate 110. In the convex area CVA, a first angle θ1 formed between the upper surface 620a and the side surface 620b may be equal to or greater than 9020 and less than 18020 . A second angle θ2 formed by the side surface 620b of the convex area CVA with respect to the substrate 110 may be an acute angle. The second light-shielding pattern 630 and the third light-shielding pattern 613 may be sequentially disposed on the convex area CVA of the first insulating layer 620, and the first light-shielding pattern 611 may be disposed under the convex area CVA of the first insulating layer 620. In this case, the convex area CVA may make the third light-shielding pattern 613 curved.

The flat areas FA of the first insulating layer 620 may be a portion of the first insulating layer 620 except for the convex areas CVA. The lenses 640 may be disposed on the flat areas FA of the first insulating layer 620 that correspond to the open areas OA. A planarization layer 650 may be in contact with portions of the upper surface of the first insulating layer 620 on which the lenses 640 and the second and third light-shielding patterns 630 and 613 are not disposed.

The lenses 640 may be disposed on the flat areas FA of the first insulating layer 620 that overlap the open areas OA. The lenses 640 may extend beyond the flat areas FA of the first insulating layer 620 to partially overlap the convex areas CVA outside the flat areas FA.

The first light-shielding pattern 611 and the second light-shielding pattern 630 may be disposed with the convex area CVA of the first insulating layer 620 interposed therebetween. In addition, the third light-shielding pattern 613 may be disposed on the convex area CVA while covering the second light-shielding pattern 630. The first light-shielding pattern 611 and the third light-shielding pattern 613 may include the same material or may have similar reflectances. Each of the first and third light-shielding patterns 611 and 613 and the second light-shielding pattern 630 may be made of different materials. In addition, each of the first and third light-shielding patterns 611 and 613 and the second light-shielding pattern 630 may have different reflectances. In the display device according to the fifth embodiment, the first to third light-shielding patterns 611, 630, and 613 may have first to third widths W1, W2, and W3, respectively, which are different from each other, and any one thereof may be formed such that the edge portion thereof is inclined with respect to the central portion thereof. In detail, the first and second widths W1 and W2 of the first and second light-shielding patterns 611 and 630 may be smaller than the third width W3 of the third light-shielding pattern 613. Because the second light-shielding pattern 630 is made of a metal, the second light-shielding pattern 630 disposed between the lenses 640 may be formed to have as small a width as possible in order to minimize or at least reduce interference between metals. Therefore, the second light-shielding pattern 630 may have a smaller width than the first light-shielding pattern 611. In addition, the edge portion of the third light-shielding pattern 613 may be formed to be inclined.

The first light-shielding pattern 611 may be disposed on the area of the encapsulation layer 180 except for the predetermined area corresponding to each of the open areas OA. The first light-shielding pattern 611 may overlap the upper surface 620a of the convex area CVA between the flat areas FA of the first insulating layer 620. In addition, the first light-shielding pattern 611 may expose at least a portion of the third light-shielding pattern 613 overlapping the side surface 620b of the first insulating layer 620 to the substrate 110.

The second light-shielding pattern 630 may be disposed on the convex area CVA of the first insulating layer 620. That is, the second light-shielding pattern 630 may be formed along the edge of each of the lenses 640. The second light-shielding pattern 630 may overlap the upper surface 620a of the convex area CVA between the flat areas FA of the first insulating layer 620. In addition, the second light-shielding pattern 630 may expose at least a portion of the third light-shielding pattern 613 overlapping the side surface 620b of the first insulating layer 620 to the substrate 110.

The third light-shielding pattern 613 may be disposed on the convex area CVA of the first insulating layer 620. The third light-shielding pattern 613 may be disposed on the second light-shielding pattern 630 while covering the entire area of the second light-shielding pattern 630. The third light-shielding pattern 613 may be formed in a shape corresponding to the shape of the upper surface 620a and the side surface 620b of the convex area CVA of the first insulating layer 620. The third light-shielding pattern 613 may be divided into a central portion that is in contact with the upper surface 620a of the convex area CVA of the first insulating layer 620 and an edge portion that is in contact with the side surface 620b of the convex area CVA of the first insulating layer 620, and the edge portion of the third light-shielding pattern 613 may be inclined with respect to the central portion thereof according to the shape of the convex area CVA of the first insulating layer 620. In other words, the edge portion of the third light-shielding pattern 613 may form a second angle θ2, which is an acute angle, with respect to the substrate 110. In addition, the central portion of the third light-shielding pattern 613 that is in contact with the upper surface 620a of the convex area CVA of the first insulating layer 620 may overlap the first light-shielding pattern 611, and the edge portion of the third light-shielding pattern 613 that is in contact with the side surface 620b of the convex area CVA of the first insulating layer 620 may be exposed to the substrate 110 from the first light-shielding pattern 611. Accordingly, light that is emitted from the light-emitting device 170a and travels to an area between the lenses 640 may be introduced into the portion of the third light-shielding pattern 613 that is exposed from the first light-shielding pattern 611, and the introduced light may be reflected to an area between the first light-shielding pattern 611 and the second light-shielding pattern 630 or may be reflected at an acute angle by the inclined edge portion of the third light-shielding pattern 613. Accordingly, the amount of light reaching another lens that does not correspond to the light-emitting device 170a due to re-reflection by reflective components of the light-emitting device 170a may be reduced.

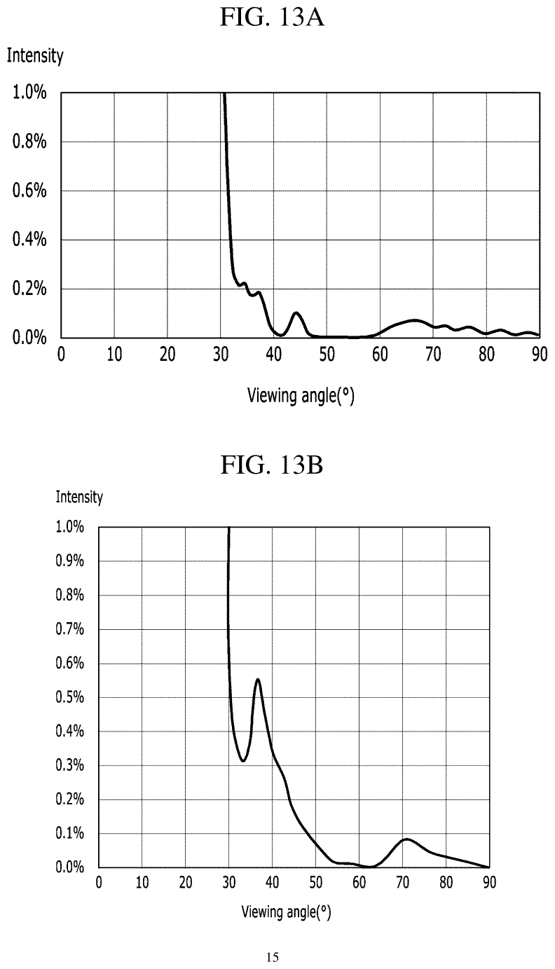

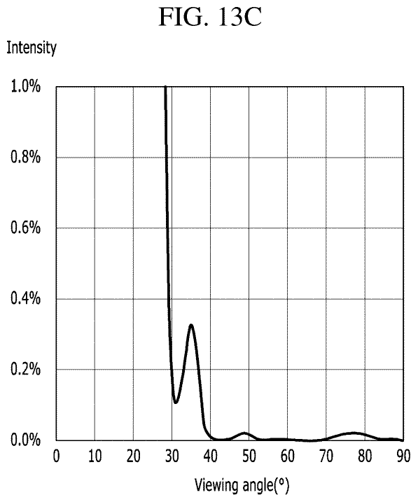

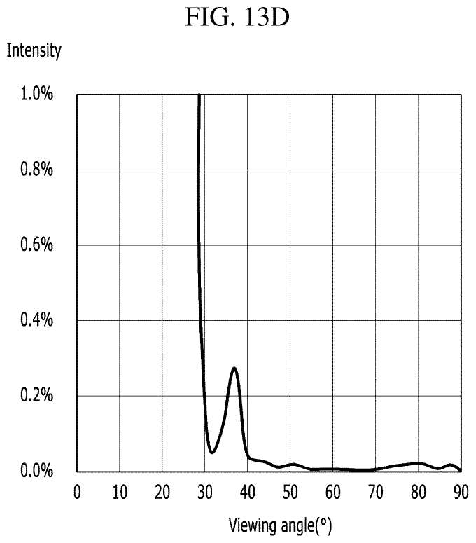

FIGS. 13A to 13D are graphs showing the intensity of light according to a viewing angle in the display devices according to the first to fourth embodiments of the present disclosure. FIG. 13A shows the intensity of light according to the viewing angle in the display device according to the first embodiment shown in FIG. 4A, which is measured under the conditions that the line width of the first light-shielding pattern 210 is 5 μm, the line width of the second light-shielding pattern 230 is 11 μm, the length of the edge portion of the second light-shielding pattern 230 is 3 μm, and the second angle θ2 is 70°. FIG. 13B shows the intensity of light according to the viewing angle in the display device according to the second embodiment shown in FIG. 6, which is measured under the conditions that the line width of the first light-shielding pattern 310 is 5 μm, the line width of the second light-shielding pattern 330 is 11 μm, the length of the edge portion of the second light-shielding pattern 330 is 3 μm, and the second angle θ2 is 70°. FIG. 13C shows the intensity of light according to the viewing angle in the display device according to the third embodiment shown in FIG. 9, which is measured under the conditions that the line width of the first light-shielding pattern 410 is 12.6 μm, the line width of the second light-shielding pattern 430 is 11 μm, the length of the edge portion of the first light-shielding pattern 410 is 3 μm, and the second angle θ2 is 70°. FIG. 13D shows the intensity of light according to the viewing angle in the display device according to the fourth embodiment shown in FIG. 10, which is measured under the conditions that the line width of the first light-shielding pattern 510 is 12.6 μm, the line width of the second light-shielding pattern 530 is 11 μm, the length of the edge portion of the first light-shielding pattern 510 is 3 μm, and the second angle θ2 is 70°. In each of the graphs, the horizontal axis indicates the viewing angle (°), and the vertical axis indicates the intensity (%) of light, which is 100% when the viewing angle is 0°.

Table 1 below shows peak values indicated in FIGS. 13A to 13D. In Table 1 below, “2nd Peak” represents the second largest peak value, and “High-Angle Peak” represents the largest peak value at a viewing angle of 60° or higher. “Conventional Structure” in Table 1 below represents a display device in which a first light-shielding pattern and a second light-shielding pattern have a flat shape having no inclined portion and overlap each other, the line width of the first light-shielding pattern is 12.6 μm, and the line width of the second light-shielding pattern is 11 μm.

TABLE 1

| | Conventional | First | Second | Third | Fourth |
|---|---|---|---|---|---|
| | Structure | Embodiment | Embodiment | Embodiment | Embodiment |
| 2^{nd} Peak (%) | 0.61 | 0.11 | 0.52 | 0.33 | 0.26 |
| High-Angle | 0.01 | 0.07 | 0.09 | 0.02 | 0.02 |
| Peak (%) | | | | | |

Referring to [Table 1], the value of “2nd Peak” is the smallest in the first embodiment, and the value of “High-Angle Peak” is the smallest in the third and fourth embodiments. If the intensity of light is about 0.1%, the light is not easily perceived by human eyes. Therefore, it can be seen from the values of “High-Angle Peak” that light leakage hardly occurs in the first to fourth embodiments. In particular, it can be seen that the amount of light leakage is the smallest in the display device according to the first embodiment in which “2nd Peak” is 0.11 and “High-Angle Peak” is 0.07. In addition, it can be seen that the values of “2nd Peak” in the display devices according to the first to fourth embodiments of the present disclosure are less than the value of “2nd Peak” (=0.61) in the conventional structure. Accordingly, the display device of the present disclosure, in which any one of the first light-shielding pattern and the second light-shielding pattern includes an inclined edge portion, may improve a cut-off effect on viewing angle limitation through the lens and may reduce a light leakage phenomenon. In particular, the display device according to the first embodiment of the present disclosure, in which “2nd Peak” is 0.11, may reliably prevent or at least reduce light leakage and may exhibit a greatly improved cut-off effect compared to the conventional structure.

A display device according to an embodiment of the present disclosure may be described as follows.

A display device according to an embodiment of the present disclosure may include a substrate including a plurality of light-emitting devices, a first insulating layer disposed on the plurality of light-emitting devices, lenses disposed on the first insulating layer so as to respectively correspond to the plurality of light-emitting devices, a first light-shielding pattern disposed between the substrate and the first insulating layer so as to correspond to an area between the plurality of light-emitting devices, and a second light-shielding pattern disposed on the first insulating layer while overlapping the first light-shielding pattern. The second light-shielding pattern may include a central portion and an edge portion formed around the central portion so as to be inclined with respect to the central portion.

According to a display device according to an embodiment of the present disclosure, the edge portion may have a first angle with respect the central portion, and the first angle may be equal to or greater than 9020 and less than 180°.

According to a display device according to an embodiment of the present disclosure, the second light-shielding pattern may have a larger width than the first light-shielding pattern.

According to a display device according to an embodiment of the present disclosure, the first light-shielding pattern may overlap the central portion of the second light-shielding pattern.

According to a display device according to an embodiment of the present disclosure, the first insulating layer may include flat areas overlapping the plurality of light-emitting devices and a convex area formed between the flat areas so as to protrude relative to the flat areas.

According to a display device according to an embodiment of the present disclosure, the central portion of the second light-shielding pattern may be disposed on an upper surface of the convex area, and the edge portion of the second light-shielding pattern may be disposed on a side surface of the convex area.

According to a display device according to an embodiment of the present disclosure, the first insulating layer may include flat areas overlapping the plurality of light-emitting devices and a concave area formed between the flat areas so as to be depressed relative to the flat areas toward the substrate.

According to a display device according to an embodiment of the present disclosure, the central portion of the second light-shielding pattern may be disposed on a bottom surface of the concave area, and the edge portion of the second light-shielding pattern may be disposed on a side surface of the concave area.

According to a display device according to an embodiment of the present disclosure, the second light-shielding pattern may have a higher reflectance than the first light-shielding pattern.

According to a display device according to an embodiment of the present disclosure, a third light-shielding pattern disposed on the second light-shielding pattern may be further included, and the third light-shielding pattern may have a lower reflectance than the second light-shielding pattern.

According to a display device according to an embodiment of the present disclosure, a fourth light-shielding pattern disposed on the first light-shielding pattern may be further included.

According to a display device according to an embodiment of the present disclosure, the lenses may include lenses having two or more different shapes.

According to a display device according to an embodiment of the present disclosure, the second light-shielding pattern may overlap portions of the edges of the lenses.

A display device according to an embodiment of the present disclosure may include a plurality of light-emitting devices disposed on a substrate; a first insulating layer disposed on the plurality of light-emitting devices; a plurality of lenses disposed on the first insulating layer, the plurality of lenses disposed to respectively correspond to the plurality of light-emitting devices; a first light-shielding pattern disposed between the substrate and the first insulating layer, the first light-shielding pattern disposed to correspond to an area between the plurality of light-emitting devices; and a second light-shielding pattern disposed on the first insulating layer, the second light-shielding pattern overlapping with the first light-shielding pattern. The first light-shielding pattern may include a central portion and an edge portion disposed around the central portion, and the edge portion may be inclined with respect to the central portion.

According to a display device according to an embodiment of the present disclosure, the edge portion may have a first angle with respect to the central portion, and the first angle may be equal to or greater than 9020 and less than 180°.

According to a display device according to an embodiment of the present disclosure, the first light-shielding pattern may have a larger width than the second light-shielding pattern.

According to a display device according to an embodiment of the present disclosure, the second light-shielding pattern may overlap the central portion of the first light-shielding pattern.

According to a display device according to an embodiment of the present disclosure, a second insulating layer disposed between the first light-shielding pattern and the substrate may be further included.

According to a display device according to an embodiment of the present disclosure, the second insulating layer may include: flat areas overlapping the plurality of light-emitting devices; and a convex area between the flat areas, the convex area protruding relative to the flat areas.

According to a display device according to an embodiment of the present disclosure, the central portion of the first light-shielding pattern may be disposed on an upper surface of the convex area, and the edge portion of the first light-shielding pattern may be disposed on a side surface of the convex area.

According to a display device according to an embodiment of the present disclosure, the second insulating layer may include: flat areas overlapping the plurality of light-emitting devices; and a concave area between the flat areas, the concave area depressed relative to the flat areas toward the substrate.

According to a display device according to an embodiment of the present disclosure, the central portion of the first light-shielding pattern may be disposed on a bottom surface of the concave area, and the edge portion of the first light-shielding pattern may be disposed on a side surface of the concave area.

According to a display device according to an embodiment of the present disclosure, a third light-shielding pattern on the first light-shielding pattern may be further included.

According to a display device according to an embodiment of the present disclosure, a fourth light-shielding pattern on the second light-shielding pattern may be further included.

According to a display device according to an embodiment of the present disclosure, the first light-shielding pattern may overlap portions of the edges of the lenses.

A display device according to an embodiment of the present disclosure may include a plurality of light-emitting devices disposed on a substrate; a first insulating layer disposed on the plurality of light-emitting devices; a plurality of lenses disposed on the first insulating layer, the plurality of lenses disposed to respectively correspond to the plurality of light-emitting devices; a first light-shielding pattern disposed between the substrate and the first insulating layer, the first light-shielding pattern disposed to correspond to areas between the plurality of light-emitting devices; a second light-shielding pattern disposed on the first insulating layer, the second light-shielding pattern overlapping with the first light-shielding pattern; and a third light-shielding pattern disposed on the first insulating layer and covering the second light-shielding pattern. The third light-shielding pattern may include a central portion and an edge portion disposed around the central portion, and the edge portion may be inclined with respect to the central portion.

According to a display device according to an embodiment of the present disclosure, the edge portion may have a first angle with respect to the central portion, and the first angle may be equal to or greater than 9020 and less than 180°.

According to a display device according to an embodiment of the present disclosure, a width of the first light-shielding pattern and a width of the second light-shielding pattern may be smaller than a width of the third light-shielding pattern, and the width of the second light-shielding pattern may be smaller than the width of the first light-shielding pattern.

According to a display device according to an embodiment of the present disclosure, the first light-shielding pattern and the second light-shielding pattern may overlap the central portion of the third light-shielding pattern.

According to a display device according to an embodiment of the present disclosure, the first insulating layer may include: flat areas overlapping the plurality of light-emitting devices; and a convex area between the flat areas, the convex area protruding relative to the flat areas.

According to a display device according to an embodiment of the present disclosure, the central portion of the third light-shielding pattern may be disposed on an upper surface of the convex area, and the edge portion of the third light-shielding pattern may be disposed on a side surface of the convex area.

According to a display device according to an embodiment of the present disclosure, the third light-shielding pattern may overlap portions of the edges of the lenses.

As is apparent from the above description, the display device of the present disclosure has the following effects.

First, since the first light-shielding pattern and the second light-shielding pattern are provided in a non-open area and any one thereof is formed to have an inclined edge portion, the display device of the present disclosure may prevent or at least reduce light that is emitted from a light-emitting device and travels to the non-open area from being reflected to the light-emitting device or may prevent or at least reduce the light re-reflected from the light-emitting device from reaching another lens that does not correspond to the light-emitting device, thereby preventing or at least reducing light leakage.

Second, according to the display device of the present disclosure, since light leakage is prevented or at least reduced, it is possible to improve cut-off effect in a display device requiring control of the viewing angle.

Third, since the display device of the present disclosure is capable of preventing or at least reducing light leakage merely by forming any one of the first light-shielding pattern and the second light-shielding pattern provided in the non-open area such that the edge portion thereof is inclined, it is possible to reduce the amount of energy consumed for production of the display device. As a result, the display device of the present disclosure is advantageous in terms of environment and process optimization, i.e., it has environment/social/governance (ESG) effects.

The effects achievable through the disclosure are not limited to the above-mentioned effects, and other effects not mentioned herein will be clearly understood by those skilled in the art from the above description.

Although exemplary embodiments of the present disclosure have been described for illustrative purposes, those skilled in the art will appreciate that various modifications, additions, and substitutions are possible, without departing from the scope and spirit of the disclosure as disclosed in the accompanying claims. Therefore, the embodiment disclosed in the present disclosure is intended to illustrate the scope of the technical idea of the present disclosure, and the scope of the present disclosure is not limited by the embodiment. The scope of the present disclosure shall be construed on the basis of the accompanying claims, and it shall be construed that all of the technical ideas included within the scope equivalent to the claims belong to the present disclosure.

What is claimed is:

1. A display device comprising:
a plurality of light-emitting devices on a substrate;
a first insulating layer on the plurality of light-emitting devices;
a plurality of lenses on the first insulating layer, the plurality of lenses disposed to respectively corresponds to the plurality of light-emitting devices;
a first light-shielding pattern between the substrate and the first insulating layer, the first light-shielding pattern corresponding to areas between the plurality of light-emitting devices; and
a second light-shielding pattern on the first insulating layer, the second light-shielding pattern overlapping the first light-shielding pattern,
wherein the second light-shielding pattern includes a central portion and an edge portion around the central portion,
wherein the edge portion is inclined with respect to the central portion.

2. The display device according to claim 1, wherein the edge portion has a first angle with respect to the central portion, and the first angle is equal to or greater than 9020 and less than 180°.

3. The display device according to claim 1, wherein the second light-shielding pattern has a width that is larger than a width of the first light-shielding pattern.

4. The display device according to claim 3, wherein the first light-shielding pattern overlaps the central portion of the second light-shielding pattern.

5. The display device according to claim 3, wherein the first insulating layer includes:
flat areas overlapping the plurality of light-emitting devices; and
a convex area between the flat areas, the convex area protruding relative to the flat areas.

6. The display device according to claim 5, wherein the central portion of the second light-shielding pattern is on an upper surface of the convex area, and the edge portion of the second light-shielding pattern is on a side surface of the convex area.

7. The display device according to claim 3, wherein the first insulating layer comprises:
flat areas overlapping the plurality of light-emitting devices; and
a concave area between the flat areas, the concave area depressed relative to the flat areas toward the substrate.

8. The display device according to claim 7, wherein the central portion of the second light-shielding pattern is on a bottom surface of the concave area, and the edge portion of the second light-shielding pattern is on a side surface of the concave area.

9. The display device according to claim 1, further comprising:
a third light-shielding pattern on the second light-shielding pattern.

10. The display device according to claim 9, wherein the third light-shielding pattern has a reflectance that is less than a reflectance of the second light-shielding pattern.

11. The display device according to claim 9, further comprising a fourth light-shielding pattern on the first light-shielding pattern.

12. The display device according to claim 1, wherein the plurality of lenses include lenses having two or more different shapes.

13. The display device according to claim 1, wherein the second light-shielding pattern overlaps portions of the edges of the lenses.

14. A display device comprising:
a plurality of light-emitting devices on a substrate;
a first insulating layer on the plurality of light-emitting devices;
a plurality of lenses on the first insulating layer, the plurality of lenses disposed to respectively correspond to the plurality of light-emitting devices;
a first light-shielding pattern between the substrate and the first insulating layer, the first light-shielding pattern corresponding to an area between the plurality of light-emitting devices; and
a second light-shielding pattern on the first insulating layer, the second light-shielding pattern overlapping the first light-shielding pattern,
wherein the first light-shielding pattern includes a central portion and an edge portion around the central portion, and
wherein the edge portion is inclined with respect to the central portion.

15. The display device according to claim 14, wherein the first light-shielding pattern has a width that is larger than a width of the second light-shielding pattern.

16. The display device according to claim 15, further comprising:
a second insulating layer between the first light-shielding pattern and the substrate.

17. The display device according to claim 15, wherein the second light-shielding pattern overlaps the central portion of the first light-shielding pattern.

18. A display device comprising:
a plurality of light-emitting devices on a substrate;
a first insulating layer on the plurality of light-emitting devices;
a plurality of lenses on the first insulating layer, the plurality of lenses disposed to respectively correspond to the plurality of light-emitting devices;
a first light-shielding pattern disposed between the substrate and the first insulating layer, the first light-shielding pattern disposed to correspond to areas between the plurality of light-emitting devices;
a second light-shielding pattern disposed on the first insulating layer, the second light-shielding pattern overlapping with the first light-shielding pattern; and
a third light-shielding pattern disposed on the first insulating layer and covering the second light-shielding pattern,
wherein the third light-shielding pattern includes a central portion and an edge portion disposed around the central portion,
wherein the edge portion is inclined with respect to the central portion.

19. The display device according to claim 18, wherein a width of the first light-shielding pattern and a width of the second light-shielding pattern are smaller than a width of the third light-shielding pattern, and the width of the second light-shielding pattern is smaller than the width of the first light-shielding pattern.

20. The display device according to claim 19, wherein the first light-shielding pattern and the second light-shielding pattern overlap the central portion of the third light-shielding pattern.
